(19) United States
(12) Patent Application Publication
(10) Pub. No.: US 2007/0133173 A1
(43) Pub. Date: Jun. 14, 2007

(54) Compact spray cooling module

(75) Inventors: Chih-Min Hsiung, Kaohsiung County (TW); Chin-Horng Wang, Tainan (TW); Szu-Wei Tang, Taichung (TW); Chiung-I Lee, Kaohsiung (TW)

Correspondence Address: BIRCH STEWART KOLASCH & BIRCH, PO BOX 747, FALLS CHURCH, VA, 22040-0747, US

(73) Assignee: Industrial Technology Research Institute

(21) Appl. No.: 11/392,872

(22) Filed: Mar. 30, 2006

(30) Foreign Application Priority Data
Dec. 13, 2005 (TW) 094144019

(51) Int. Cl. H05K 7/20

(52) U.S. Cl. 361/699

(57) ABSTRACT

A compact spray cooling module is presented, which comprises: a storage tank, a spray chamber, a nebulizer, and a media of liquid transportation ability. The storage tank is used for storing a cooling liquid, and the spray chamber is connected to a heat source. Moreover, there is a nebulizer lay on the spray chamber, whereas the nebulizer is comprised of a piezoelectric plate and a micro-nozzle plate. The micro-nozzle plate has a large number of micro-nozzle disposed on it. Furthermore, the media located between the storage tank and the spray chamber has the capability of transporting the cooling liquid from storage tank to spray chamber by capillary attraction for the purpose of nebulizing the cooling liquid. Taking advantage of the latent heat from liquid phase change, the nebulized cooling liquid sprayed to the bottom of the spraying chamber can dissipate the heat generated from the heat source rapidly. Moreover, the cooling module of the invention can combine with a condenser and a transportation piping system to form a compact and closed spray cooling module.

### FIELD OF THE INVENTION

The present invention relates to a heat dissipating apparatus, and more particularly, to a compact spray cooling module capable of utilizing the vibrations generated from a piezoelectric unit thereof to break the surface tension of a cooling liquid while the cooling liquid is guided to be disposed on a piezoelectric unit for enabling the spray cooling module to nebulize the cooling liquid continuously and thus to be used for dissipating heat from a heat source as the nebulized cooling liquid is evaporating.

### BACKGROUND OF THE INVENTION

With the advent of semiconductor devices having increasingly large component densities, the removal of heat generated by the devices has become an increasingly challenging technical issue. Generally, semiconductor devices and their associated components are cooled by natural or forced air convection which, because of the relatively poor thermal capacitance and heat transfer coefficients of air, is no longer capable of satisfying the heat dissipating requirement of current semiconductor devices of high heat flux.

Evaporative spray cooling system features the spraying of atomized fluid droplets directly onto a surface of a heat source such as a semiconductor device. When the fluid droplets impinge upon the device's surface, a thin film of fluid coats the device, and heat is removed primarily by evaporation of the fluid from the device's surface. Since the latent heat of evaporation of any liquid is usually high, the evaporative spray cooling is a preferred method of heat removal in many electronic devices of high heat flux. There are therefore many spray cooling systems being successfully applied in aviation, military electronic systems and high power laser system as heat dissipating devices. However, in order to employ the spray cooling system as the heat dissipating device of general information/electronic devices, a compact, reliable and cost-efficient spray cooling system is required.

Please refer to FIG. 1, which is a schematic representation of a spray cooling system disclosed in U.S. Pat. No. 6,205,799. In the spray cooling system o FIG. 1, cooling liquid is driven by a pump 23 to flow from a storage tank 25 into a nebulizer 21 to be nebulized into atomized cooling liquid droplets 22 while being sprayed directly onto a surface of a heat source 20 such as a semiconductor device, and as the droplets impinge upon the device's surface, heat is absorbed by the droplets and removed primarily by evaporation of the atomized cooling liquid from the device's surface while the evaporated cooling liquid is being fed to a heat exchange 24 to be liquefied or condensed, thereafter, the condensed cooling liquid is drawn back to the storage tank 25 by the assistance of the pump 23 so as to complete a cooling cycle of the spray cooling system. However, the pump used by the spray cooling system disclosed in U.S. Pat. No. 6,205,799 for assisting the circulation of the cooling liquid is going to cause the size and the manufacturing cost of the spry cooling system to increase. Moreover, the nebulizer of the spray cooling system disclosed in U.S. Pat. No. 6,205,799 employs a nozzle design similar to that of a ink-jet print head which generate micro droplets by heating the cooling liquid, that the thermal ink-jet type of nebulizer will require comparatively higher power consumption. Except for the aforesaid spray cooling system, the apparatus for spray cooling an electronic module as disclosed in U.S. Pat. No. 5,687,577 also utilizes a pump as the power source of circulation, so that it is also suffer the same disadvantages of large volume and high cost.

From the above description, there is therefore a need for a compact spray cooling module which may overcome the aforesaid shortcomings of large volume, high cost and high power consumption.

### SUMMARY OF THE INVENTION

In view of the disadvantages of prior art, the primary object of the present invention is to provide a compact spray cooling module of low power consumption capable of generating atomized cooling liquid by a piezoelectric unit.

It is another object of the invention to provide a compact spray cooling module utilizing a means of capillary attraction instead of the pump used in conventional spray cooling devices for enabling cooling liquid to circulate in the spray cooling module by self-pumping.

It is yet another object of the invention to provide a compact spray cooling module, which combines a nebulizer, a circulation circuit, a storage tank and a condenser to form a small and integrated module.

To achieve the above objects, the present invention provides a compact spray cooling module, which comprises: a storage tank, for storing a cooling liquid; a spray chamber, connected to a heat source; a nebulizer, arranged at the top portion of the spray chamber, further comprising a piezoelectric plate and a micro-nozzle plate with a plurality of micro-nozzles disposed thereon; and a media of liquid transportation ability; wherein the media has the capability of transporting the cooling liquid from the storage tank to the nebulizer by capillary attraction for enabling the cooling liquid to be atomized by the nebulizer and sprayed into the spray chamber for absorbing and removing thermal energy from the heat source.

Preferably, the compact spray cooling module further comprises a heat-absorbing plate, which is arranged between the spray chamber and the heat source for enabling a surface thereof to connect to the heat source and another surface thereof to be impinged by the atomized cooling liquid. Moreover, the surface of the heat-absorbing plate to be impinged by the atomized cooling liquid has a plurality of microstructures arranged thereon.

Preferably, the media of liquid transportation ability is a capillary structure. Moreover, the capillary structure can be made of a metal material, a ceramic material, a cotton material, or a fiber material.

Preferably, the media of liquid transportation ability further comprises a plurality of microchannels, each having an end connected to the storage tank and another end arranged over the nebulizer. Moreover, each microchannel is filled with a capillary structure, whereas the capillary structure can be made of a metal material, a ceramic material, a cotton material, or a fiber material.

Preferably, the nebulizer is connected to a condenser by a vapor piping, whereas the condenser is connected to the storage tank by a condense piping. Moreover, the condenser can be a fan or a structure with heat dissipating fins.

According to a preferred embodiment of the invention, a compact spray cooling module is comprised of: a shell, connected to a heat source, having a space enclosed thereby being divided into a spray chamber, a vapor chamber, a condense chamber, and a liquid storage chamber; a nebulizer, arranged at the top portion of the spray chamber, further comprising a piezoelectric plate and a micro-nozzle plate with a plurality of micro-nozzles disposed thereon; and a media of liquid transportation ability; wherein the media has the capability of transporting a cooling liquid stored in the liquid storage chamber to the nebulizer by capillary attraction for enabling the cooling liquid to be atomized by the nebulizer and sprayed into the spray chamber for absorbing and removing thermal energy from the heat source, and the spray chamber is channeled to the vapor chamber while the vapor chamber is channeled to the condense chamber as the condense chamber is channeled to the liquid storage chamber.

Preferably, fins or fans can be arranged on the shell at the position corresponding to the condense chamber for enhancing the heat to be removed from the evaporated cooling liquid flowing in the condense chamber while condensing the same.

Other aspects and advantages of the present invention will become apparent from the following detailed description, taken in conjunction with the accompanying drawings, illustrating by way of example the principles of the present invention.

### BRIEF DESCRIPTION OF THE DRAWINGS

FIG. 1 is a schematic representation of a spray cooling system disclosed in U.S. Pat. No. 6,205,799.

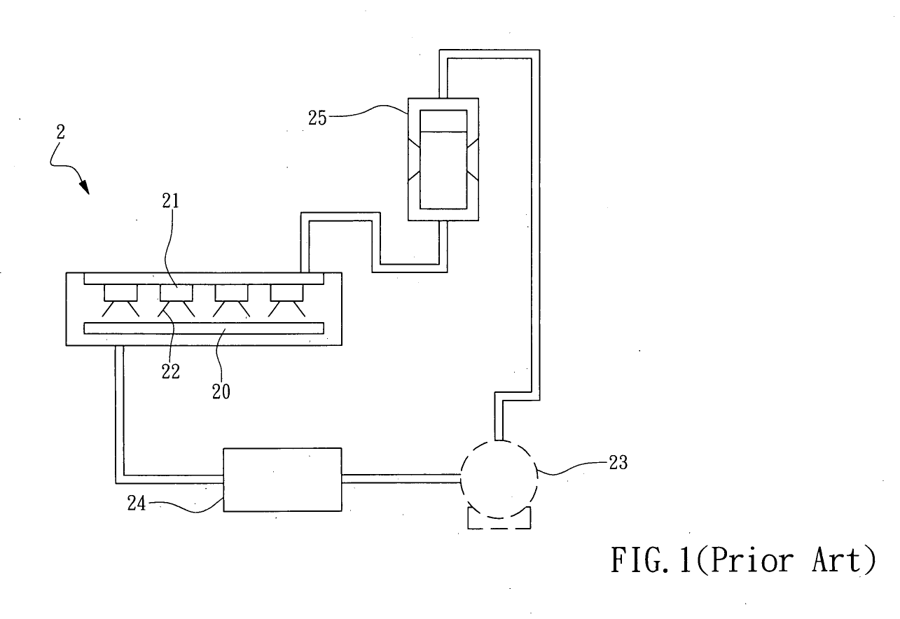

FIG. 2A is a schematic representation of a spray cooling module according to a first preferred embodiment of the invention.

FIG. 2B is a schematic representation of the nebulizer of FIG. 2A.

FIG. 3 is a schematic sectional view of a heat-absorbing plate used in a spray cooling module of the present invention.

FIG. 4 is schematic diagram illustrating the operating of the spray cooling module of FIG. 2A.

FIG. 5 is a schematic representation of a spray cooling module according to a second preferred embodiment of the invention.

### DESCRIPTION OF THE PREFERRED EMBODIMENT

For your esteemed members of reviewing committee to further understand and recognize the fullfilled functions and structural characteristics of the invention, several preferable embodiments cooperating with detailed description are presented as the follows.

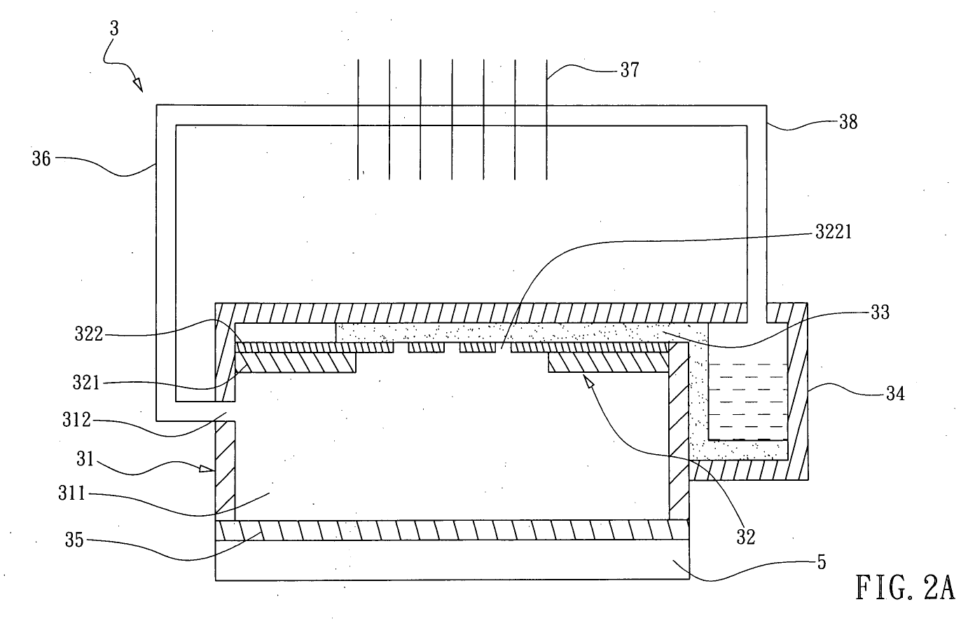

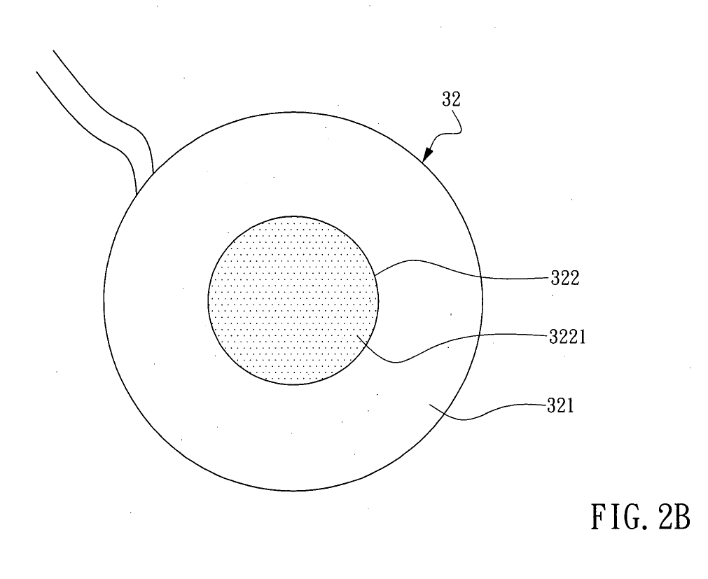

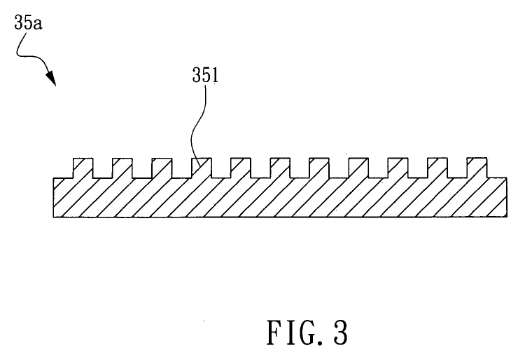

Pleased refer to FIG. 2A, which is a schematic representation of a spray cooling module according to a first preferred embodiment of the invention. The spray cooling module 3 shown in FIG. 2A is comprised of a spray chamber 31, a storage tank 34, a nebulizer 32 and a media of liquid transportation ability 33. The spray chamber is a hollow structure of specific volume, which encloses a space 311 to be sprayed by atomized cooling liquid. Preferably, the bottom of the spray chamber 31 is formed by a heat-absorbing plate 35, which is abutted upon a heat source 5 by a surface thereof for absorbing heat therefrom and another surface thereof to be impinged by the atomized cooling liquid of the spray chamber. The heat-absorbing plate 35 is preferred to be made of a material with high thermal conductivity such as copper or aluminum. Please refer to FIG. 3, which is a schematic sectional view of a heat-absorbing plate used in a spray cooling module of the present invention. In FIG. 3, a plurality of microstructures 351 are formed by means of precision machining or MEM processing on the surface of the heat absorbing plate 35a impinged by the atomized cooling liquid, that the plural microstructures 351 are used to enhance the performance of the spray cooling module 3. The plural microstructures shown in FIG. 2 are a plurality of embossed patterns, however, the formation of the microstructure 351 is not limited thereby, only if it is capable of enhancing the evaporation of the thin film formed by the atomized cooling liquid on the heat-absorbing plate 35a. Moreover, the heat source can be a CPU or other chips.

As seen in FIG. 2A, an outlet 312 for evaporated cooling liquid to exit from the spray chamber 31 can be arranged at a side or on top of the spray chamber, whereas the storage tank 34 is arranged next to a side of the spray chamber 31 for storing a cooling liquid 90 such as water or refrigerant. It is noted that the spray chamber 31 can be a structure integrally formed by means of forging, stamping, and CNC processing, etc., or can be an assembly of individually formed shells and base. Similarly, the storage tank 34 also can be a structure integrally formed by means of forging, stamping, and CNC processing, etc., or can be an assembly of individually formed shells and base.

Please refer to FIG. 2B, which is a schematic representation of the nebulizer of FIG. 2A. The nebulizer 32 is a structure composed of a circular piezoelectric plate 321 and a thin micro-nozzle plate 322 with a plurality of micro-nozzles 3220 disposed thereon. Moreover, the micro-nozzle plate 322 can be manufactured by means of micro electroforming or other micro processing techniques. It is noted that the piezoelectric plate 321 and the micro-nozzle plate 322 can be assembled by a gluing means or other means that is not going to damage the piezoelectric plate 321 and the micro-nozzle plate 322. Moreover, the nebulizer 32 is fixed on the top portion of the spray chamber 31 by a proper fixing means.

In the preferred embodiment shown in FIG. 2A, the media of liquid transportation ability 33 is a capillary structure, which has a specific length. It is noted that the media 33 can be made of a material such as metal, ceramics, cotton, fiber, etc., by processing the same with means such as weaving, sintering, or precision machining, and so on. In a preferred embodiment, the media 33 can be a structure having a plurality of microchannel formed therein, whereas each microchannel is small enough to induce capillary effect while the structure is made of a material such as metal, ceramics, cotton, fiber, etc. Moreover, each microchannel can be filled with a capillary structure for enhancing the capillary attraction thereof. In FIG. 2A, an end of the media 33 is immersed in the cooling liquid stored in the storage tank 34 while another end thereof is abutted to the micro-nozzle plate 322 of the nebulizer 32. To construct a cooling circulation circuit, the outlet 312 is connected to a condenser 37 by a vapor piping 36 while the condenser 37 is connected to the storage tank 34 by a condense piping 38.

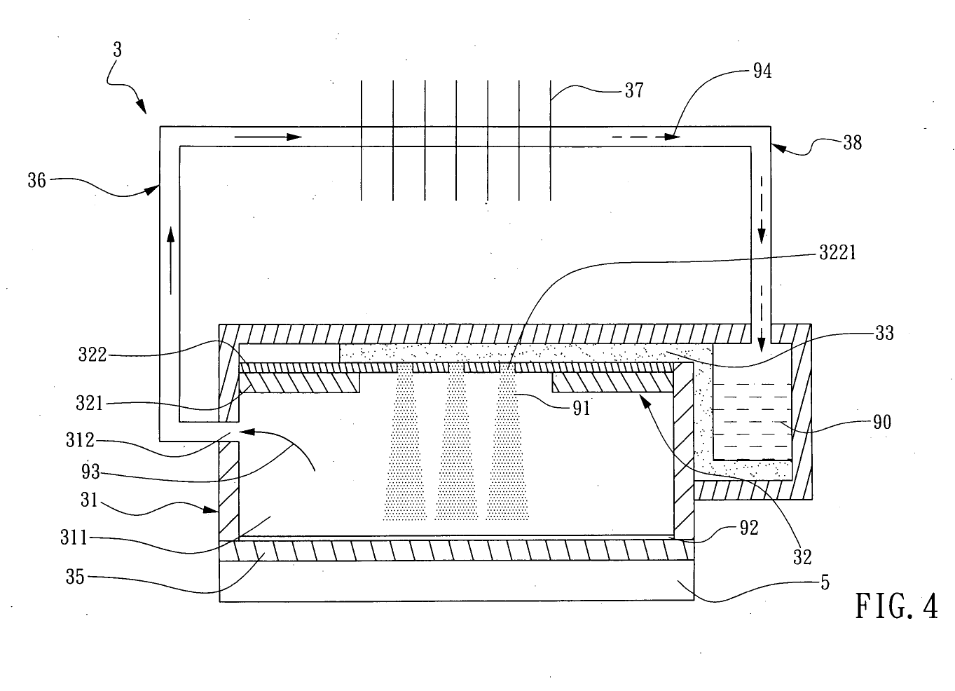

Please refer to FIG. 4, which is schematic diagram illustrating the operating of the spray cooling module of FIG. 2A. Operationally, the cooling liquid stored in the storage tank 34 is transported from the storage tank 34 to the top of the micro-nozzle plate 322 by the media 33. As the circular piezoelectric plate 321 is driven by a voltage to vibrate radially, the radial vibration of the piezoelectric plate 321 will be transmitted to the micro-nozzle plate 322 for enabling the same to vibrate axially. As the micro-nozzle plate 322 is vibrating axially, the surface tension of the cooling liquid deposited on the micro-nozzle plate 322 will be broken for enabling the micro-nozzle plate 322 to atomize the cooling liquid continuously while spraying the atomized cooling liquid 91 form the bottom of the micro-nozzle plate 322 upon the heat-absorbing plate 35 abutting against the heat source 5 and forming a thin film 92 of cooling liquid thereon. As the surface temperature of the heat-absorbing plate 35 is higher than the saturation temperature of the atomized cooling liquid, the cooling liquid will be evaporated while bring a great amount of heat therewith, that the heat is dissipated from the heat source. The evaporated cooling liquid 93 can be discharged out of the spray chamber 31 from the outlet 312 formed on top of the spray chamber 31 and enters the vapor piping 36 to be transport to the condenser 37. As the evaporated cooling liquid enters the condenser, the evaporated cooling liquid can be condensed into liquefied cooling liquid. Finally, the liquefied cooling liquid is fed back to the storage tank 34 through the condense piping 38 so as to complete a circulation of self-pumping. It is noted that the circulation of the spray cooling module of the invention can be achieved without the help of a pump used in those conventional spray cooling devices.

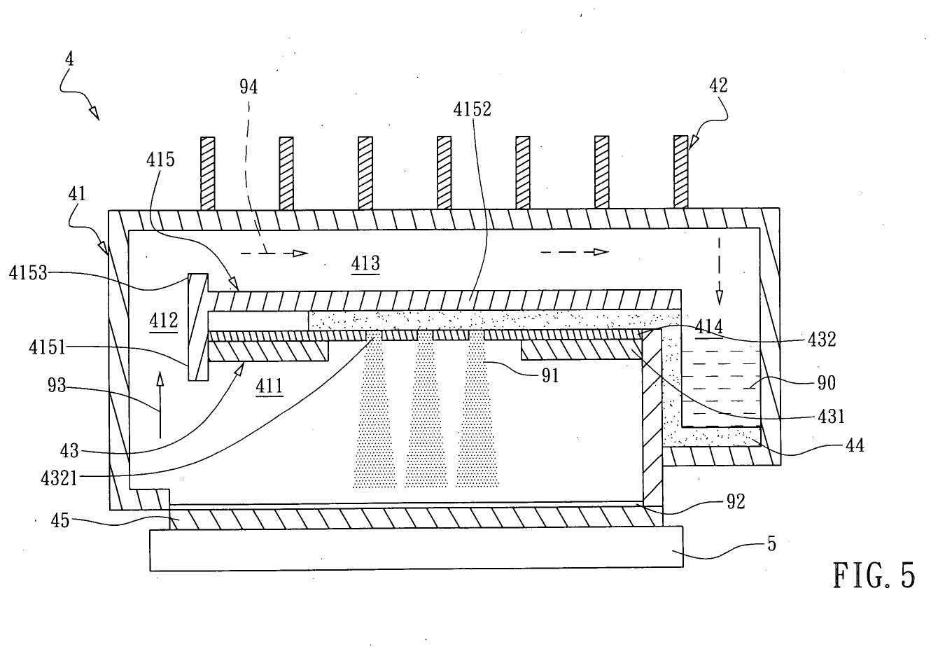

Please refer to FIG. 5, which is a schematic representation of a spray cooling module according to a second preferred embodiment of the invention. In order to further reduce the volume of the spray cooling module as shown in the first embodiment of FIG. 2A, the spray cooling module 4 of the second embodiment integrated the spray chamber, the nebulizer, the pipings, the storage tank and the condenser into a compact structure.

In FIG. 5, the spray cooling module. 4 is comprised of a shell 41, a nebulizer 43, and a media of liquid transportation ability 44. The shell 41 is connected to a heat source 5 by a heat-absorbing plate 45 thereof, which has a space enclosed thereby being divided into a spray chamber 411, a vapor chamber 412, a condense chamber 413, and a liquid storage chamber 414, respectively by the cooperation of a vapor plate 4151 and a condense plate 4151, whereas the assembling of the vapor plate 4151 and the condense plate 4152 forms a separating plate structure 415. Moreover, he spray chamber 411 is channeled to the vapor chamber 412 while the vapor chamber 412 is channeled to the condense chamber 413 as the condense chamber 413 is channeled to the liquid storage chamber 414 for storing a cooling liquid 90.

The nebulizer 43 is arranged at the top portion of the spray chamber 411, which further is comprised of a piezoelectric plate 431 and a micro-nozzle plate 432 with a plurality of micro-nozzles 4321 disposed thereon. The nebulizer 43 is capable of atomizing the cooling liquid 90 and spraying the atomized cooling liquid into the spray chamber 411 for absorbing and removing thermal energy from the heat source 5. The media of liquid transportation ability 44 has the capability of transporting the cooling liquid 90 stored in the liquid storage chamber 414 to the nebulizer 43 by capillary attraction, which is configured similar to that described hereinbefore and this is not describe further. Moreover, a condenser 42 is further arranged on the shell 41 at the position corresponding to the condense chamber 413 for removing heat from evaporated cooling liquid flowing in the condense chamber 413 while liquefying the same.

Operationally, the cooling liquid 90 stored in the liquid storage chamber 414 is transported from the liquid storage chamber 414 to the top of the micro-nozzle plate 432 by the media 44. As the circular piezoelectric plate 431 is driven by a voltage to vibrate continuously or periodically, the vibration of the piezoelectric plate 431 will be transmitted to the micro-nozzle plate 432 for enabling the same to vibrate. As the micro-nozzle plate 431 is vibrating, the cooling liquid 90 will be atomized thereby as it is flowing passing through the plural micro-nozzles 4321, and the atomized cooling liquid 91 will be sprayed into the spray chamber 411 upon the heat-absorbing plate 45 abutting against the heat source 5 and forming a thin film 92 of cooling liquid thereon. As the surface temperature of the heat-absorbing plate 45 is higher than the saturation temperature of the atomized cooling liquid, the cooling liquid will be evaporated while bring a great amount of heat therewith, that the heat is dissipated from the heat source. The evaporated cooling liquid 93 can be discharged out of the spray chamber 411 from the vapor chamber 412 and enters the condense chamber 413 to be transport to the condenser 42. As the evaporated cooling liquid 93 enters the condenser 42, the evaporated cooling liquid 93 can be condensed into liquefied cooling liquid 94. Finally, the liquefied cooling liquid 94 is fed back to the liquid storage chamber 414 through the condense chamber 413 so as to complete a circulation of self-pumping. It is noted that a bulge 4153 is formed on the separating plate structure 415 for preventing the revere flow of the liquefied cooling liquid 93. Moreover, the condenser 42 can be a fan or a structure with heat dissipating fins, bit is not limited thereby.

To sum up, the a compact spray cooling module of the invention utilizes a means of capillary attraction instead of the pump used in conventional spray cooling devices for enabling cooling liquid to circulate in the spray cooling module by self-pumping, that is a compact device of low power consumption.

While the preferred embodiment of the invention has been set forth for the purpose of disclosure, modifications of the disclosed embodiment of the invention as well as other embodiments thereof may occur to those skilled in the art. Accordingly, the appended claims are intended to cover all embodiments which do not depart from the spirit and scope of the invention.

What is claimed is:

1. A compact spray cooling module, comprising:
a storage tank, for storing a cooling liquid;
a spray chamber, connected to a heat source;
a nebulizer, arranged at the top portion of the spray chamber, further comprising a piezoelectric plate and a micro-nozzle plate with a plurality of micro-nozzles disposed thereon; and
a media of liquid transportation ability;
wherein the media has the capability of transporting the cooling liquid from the storage tank to the nebulizer by capillary attraction for enabling the cooling liquid to be atomized by the nebulizer and sprayed into the spray chamber for absorbing and removing thermal energy from the heat source.

2. The compact spray cooling module of claim 1, further comprising a heat-absorbing plate, arranged between the spray chamber and the heat source for enabling a surface thereof to connect to the heat source for absorbing heat therefrom and another surface thereof to be impinged by the atomized cooling liquid of the spray chamber.

3. The compact spray cooling module of claim 2, wherein the surface of the heat-absorbing plate to be impinged by the atomized cooling liquid has a plurality of microstructures arranged thereon.

4. The compact spray cooling module of claim 1, wherein the media of liquid transportation ability is structured as a capillary structure.

5. The compact spray cooling module of claim 4, wherein the capillary structure is made of a material selected from the group consisting of a metal material, a ceramic material, a cotton material, and a fiber material.

6. The compact spray cooling module of claim 1, wherein the media of liquid transportation ability further comprises a plurality of microchannels, each having an end connected to the storage tank and another end arranged over the nebulizer.

7. The compact spray cooling module of claim 6, wherein each microchannel is filled with a capillary structure.

8. The compact spray cooling module of claim 7, wherein the capillary structure is made of a material selected from the group consisting of a metal material, a ceramic material, a cotton material, and a fiber material

9. The compact spray cooling module of claim 1, wherein the nebulizer is connected to a condenser by a vapor piping.

10. The compact spray cooling module of claim 9, wherein the condenser is connected to the storage tank by a condense piping

11. A compact spray cooling module, comprising:
a shell, connected to a heat source, having a space enclosed thereby being divided into a spray chamber, a vapor chamber, a condense chamber, and a liquid storage chamber;
a nebulizer, arranged at the top portion of the spray chamber, further comprising a piezoelectric plate and a micro-nozzle plate with a plurality of micro-nozzles disposed thereon; and
a media of liquid transportation ability;
wherein the media has the capability of transporting a cooling liquid stored in the liquid storage chamber to the nebulizer by capillary attraction for enabling the cooling liquid to be atomized by the nebulizer and sprayed into the spray chamber for absorbing and removing thermal energy from the heat source, and the spray chamber is channeled to the vapor chamber while the vapor chamber is channeled to the condense chamber as the condense chamber is channeled to the liquid storage chamber.

12. The compact spray cooling module of claim 11, further comprising a heat-absorbing plate, arranged between the spray chamber and the heat source for enabling a surface thereof to connect to the heat source for absorbing heat therefrom and another surface thereof to be impinged by the atomized cooling liquid of the spray chamber.

13. The compact spray cooling module of claim 12, wherein the surface of the heat-absorbing plate to be impinged by the atomized cooling liquid has a plurality of microstructures arranged thereon.

14. The compact spray cooling module of claim 11, wherein the media of liquid transportation ability is a capillary structure.

15. The compact spray cooling module of claim 14, wherein the capillary structure is made of a material selected from the group consisting of a metal material, a ceramic material, a cotton material, and a fiber material.

16. The compact spray cooling module of claim 11, wherein the media of liquid transportation ability further comprises a plurality of microchannels, each having an end connected to the liquid storage chamber and another end connected to the top portion of the spray chamber.

17. The compact spray cooling module of claim 16, wherein each microchannel is filled with a capillary structure.

18. The compact spray cooling module of claim 17, wherein the capillary structure is made of a material selected from the group consisting of a metal material, a ceramic material, a cotton material, and a fiber material.

19. The compact spray cooling module of claim 11, wherein a condenser is further arranged on the shell at the position corresponding to the condense chamber for removing heat from evaporated cooling liquid flowing in the condense chamber while liquefying the same.

20. The compact spray cooling module of claim 19, wherein the condenser is a device selected form the group consisting of a fan and a structure with heat dissipating fins.
